(19) United States
(12) Patent Application Publication
(10) Pub. No.: US 2013/0308395 A1
(43) Pub. Date: Nov. 21, 2013

(54) DATA OUTPUT CIRCUIT AND SEMICONDUCTOR MEMORY DEVICE

(71) Applicant: Mi Hyun HWANG, Seoul (KR)

(72) Inventor: Mi Hyun HWANG, Seoul (KR)

(73) Assignee: SK hynix Inc., Icheon-si (KR)

(21) Appl. No.: 13/613,791

(22) Filed: Sep. 13, 2012

(30) Foreign Application Priority Data
May 21, 2012 (KR) 10-2012-0053905

(51) Int. Cl. G11C 7/10

(52) U.S. Cl. 365/189.05

(57) ABSTRACT

A semiconductor memory device including internally generated control signals that help to ensure that buffered and amplified data from a memory cell is properly presented to a global line independent of the enable period of the internally generated enable signal EN. in the semiconductor memory device in accordance with an embodiment of the present invention, since data is outputted through the global line commonly connected to multiple banks, pre-charge signal generation units are disposed in the respective banks to prevent contention on the global line.

### CROSS-REFERENCE TO RELATED APPLICATION

The present application claims priority under 35 U.S.C. 119(a) to Korean Patent Application No. 10-2012-0053905 filed on May 21, 2012 in the Korean Intellectual Property Office, which is incorporated herein by reference in its entirety set forth in full.

### BACKGROUND

In general, a semiconductor memory device includes a plurality of banks. When the semiconductor memory device receives a READ command, the semiconductor memory device outputs the data stored in a memory cell through a global line which is commonly connected to the plurality of banks. The semiconductor memory device can receive consecutive READ commands, and a time defined as a specification in this regard is tCCD (CAS to CAS delay, where CAS is Column Address Strobe). The tCCD is a time that elapses from after a first output enable signal (YI) is enabled to until the next output enable signal (YI) is enabled. The output enable signal (YI) is a signal which is generated by decoding a column address. When the semiconductor memory device receives a READ command, the data present on a bit line is outputted to a local line during a period in which the output enable signal (YI) is enabled. For a DDR2 (double data rate 2) semiconductor memory device, a first READ operation should normally be performed even when a next READ command is applied after two cycles of a clock elapse after the first READ command is applied; that is, even in the case where tCCD is two cycles of the clock.

FIG. 1 is a block diagram showing a semiconductor memory device including a conventional data output circuit.

The semiconductor memory device includes first to fourth banks 11 to 14, respectively. The first bank 11 includes an input/output sense amplifier 15 and an output unit 16. The second to fourth banks 12 to 14 also include input/output sense amplifiers (not shown) and output units (not shown). When a READ command (RD) is applied to the semiconductor memory device, an enable signal EN is enabled. The enable signal EN is a signal which is enabled to a logic high level (or a logic low level according to an embodiment) when a READ command (RD) is applied to the semiconductor memory device. During a period in which the enable signal EN is enabled, the input/output sense amplifier 15 performs operations of sensing and amplifying data DIN and inverted data DINB.

The input/output sense amplifier 15 is realized in a cross-coupled latch type. The input/output sense amplifier 15 senses and inversion-amplifies the data DIN and the inverted data DINB which are respectively transferred through a local line LIO and a complementary local line LIOB during the period in which the enable signal EN is enabled, and generates amplified data ADIN and inverted amplified data ADINB. The output unit 16 includes a PMOS transistor P13, an inverter IV13 and an NMOS transistor N13. The output unit 16 outputs output data OUTDATA of a logic high level to a global line GIO when the amplified data ADIN has a logic low level, and outputs output data OUTDATA of a logic low level to the global line GIO when the inverted amplified data ADINB has a logic low level.

The operations of the input/output sense amplifier 15 of sensing and inversion-amplifying the data DIN and the inverted data DINB and generating the amplified data ADIN and the inverted amplified data ADINB are performed during the pulse width of the enable signal EN, that is, the enable period of the enable signal EN. The output unit 16 receives the amplified data ADIN and the inverted amplified data ADINB and outputs the output data OUTDATA to the global line GIO. Accordingly, since the output data OUTDATA is generated by driving the global line GIO during the period in which the enable signal EN is enabled, it is important to set the pulse width of the enable signal EN, that is, the enable period of the enable signal EN.

However, in this connection, difficulties exist in setting the enable period of the enable signal EN because of a variation in the skew of the enable signal EN according to PVT (process, voltage and temperature). Cases where the enable period of the enable signal EN is set to be short and long will be described below with reference to FIGS. 2 and 3.

FIG. 2 is a timing diagram illustrating a case where the enable period of the enable signal EN is set to be short. In this example, a first READ command RD is applied to the semiconductor memory device, and the semiconductor memory device outputs the output data OUTDATA of the logic high level. A second READ command RD is then applied to the semiconductor memory device after two cycles of a clock CLK, and the semiconductor memory device outputs the output data OUTDATA of the logic low level.

As the first READ command RD is applied to the semiconductor memory device at a time T1, the enable signal EN is enabled at a time T2. The input/output sense amplifier 15 senses and inversion-amplifies the data DIN and the inverted data DINB during the period in which the enable signal EN is enabled, and generates the amplified data ADIN and the inverted amplified data ADINB. In this example, however, since the enable signal EN is set to have a short enable period, the output unit 16 cannot drive the global line GIO to a preset internal voltage VINT.

As the second READ command RD is applied to the semiconductor memory device at a time T3, the enable signal EN is enabled at a time T4. The input/output sense amplifier 15 senses and inversion-amplifies the data DIN and the inverted data DINB during the period in which the enable signal EN is enabled, and generates the amplified data ADIN and the inverted amplified data ADINB. The output unit 16 receives the amplified data ADIN and the inverted amplified data ADINB and outputs the output data OUTDATA of the logic low level to the global line GIO.

FIG. 3 is a timing diagram illustrating a case where the enable period of the enable signal EN is set to be long. In this example, a first READ command RD is applied to the semiconductor memory device, and the semiconductor memory device outputs the output data OUTDATA of the logic high level. A second READ command RD is then applied to the semiconductor memory device after two cycles of the clock CLK, and the semiconductor memory device outputs the output data OUTDATA of the logic low level.

As the first READ command RD is applied to the semiconductor memory device at a time T5, the enable signal EN is enabled at a time T6. The input/output sense amplifier 15 senses and inversion-amplifies the data DIN and the inverted data DINB during the period in which the enable signal EN is enabled, and generates the amplified data ADIN and the inverted amplified data ADINB. The output unit 16 receives the amplified data ADIN and the inverted amplified data ADINB and outputs the output data OUTDATA of the logic high level to the global line GIO.

Next, as the second READ command RD is applied to the semiconductor memory device at a time T7, the enable signal EN is enabled. In this example, however, since the enable signal EN is set to have a long enable period, the enable signal EN enabled by the second READ command RD is mixed with the enable signal EN enabled by the first READ command RD. Hence, the input/output sense amplifier 15 senses and inversion-amplifies the data DIN and the inverted data DINB during a period in which the enable signal EN enabled by the first READ command RD and the enable signal EN enabled by the second READ command RD are mixed, and generates the amplified data ADIN and the inverted amplified data ADINB. The output unit 16 receives the amplified data ADIN and the inverted amplified data ADINB and outputs the output data OUTDATA of the logic high level to the global line GIO during the period in which the enable signal EN enabled by the first READ command RD and the enable signal EN enabled by the second READ command RD are mixed. Therefore, the semiconductor memory device cannot output the output data OUTDATA by the second READ command RD.

In the conventional semiconductor memory device, the output data OUTDATA is generated by driving the global line GIO during the pulse width of the enable signal EN for controlling the operations of the input/output sense amplifier 15; that is, during the period in which the enable signal EN is enabled. Accordingly, in the conventional semiconductor memory device, depending upon the enable period of the enable signal EN, the global line GIO may not be driven to the preset internal voltage VINT. In other words, the output data OUTDATA may not be outputted properly in response to the second READ command RD in the case where the second READ command RD is consecutively applied after the output data OUTDATA is outputted in response to receiving the first READ command RD.

### SUMMARY

Embodiments of the present invention relate to a data output circuit which can drive a global line and output output data regardless of the enable period of an enable signal for controlling operations of an input/output sense amplifier, such that the output data can be stably outputted even when READ commands are consecutively applied, and a semiconductor memory device including the same.

In one embodiment, a data output circuit includes: an input/output sense amplifier configured to sense and amplify data and inverted data in response to an enable signal, and generate amplified data and inverted amplified data; a control pulse generation unit configured to generate a control pulse in synchronization with an enable time of the enable signal; and a signal generation unit configured to latch the amplified data and the inverted amplified data in response to the control pulse, and generate a pull-up signal and a pull-down signal.

In another embodiment, a semiconductor memory device includes first to fourth banks, the first bank including: an input/output sense amplifier configured to sense and amplify data and inverted data in response to an enable signal, and generate amplified data and inverted amplified data; a control pulse generation unit configured to generate a control pulse in synchronization with an enable time of the enable signal; a precharge signal generation unit configured to generate a precharge signal which is enabled when any one of the second to fourth banks performs a read or write operation; and a signal generation unit configured to latch the amplified data and the inverted amplified data in response to the control pulse and the precharge signal, and generate a pull-up signal and a pull-down signal.

In a further embodiment, a method is introduced for a DDR2 semiconductor memory device for ensuring that a READ operation is properly performed even when a subsequent READ command is received after only two clock cycles. The method comprises the steps of generating an internal enable signal in response to receipt of a READ command, the internal enable signal having a leading edge defining a start of an enable period; generating an internal control pulse proximate the leading edge of the internal enable signal; applying the internal control pulse to a signal generation unit in which amplified data from memory cells within the semiconductor memory device are buffered and latched; deriving a pull-up signal and a pull-down signal from the internal control pulse and the amplified data; and applying the pull-up signal and the pull-down signal to an output unit that presents output data corresponding to the amplified data from the memory cells to a global line in response to the pull-up signal and the pull-down signal. In this way, output data is presented to the global line proximate the leading edge of the enable signal, and effectively independent of the enable period of the enable signal.

Accordingly, a global line can be stably driven and output data can be outputted, regardless of PVT (process, voltage and temperature).

### BRIEF DESCRIPTION OF THE DRAWINGS

The above and other aspects, features and other advantages will be more clearly understood from the following detailed description taken in conjunction with the accompanying drawings, in which:

FIG. 1 is a block diagram showing a semiconductor memory device including a conventional data output circuit;

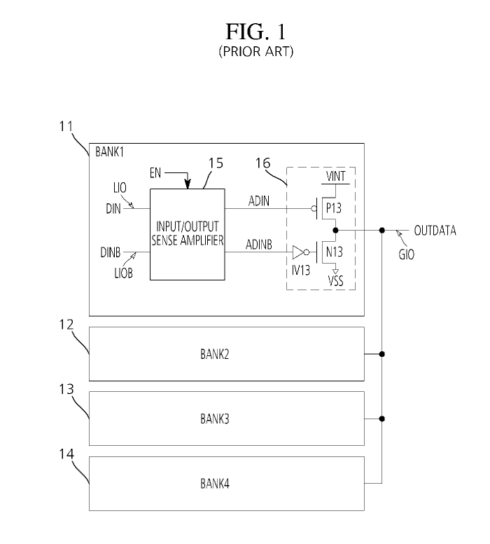

FIG. 2 is a timing diagram illustrating a case where the enable period of an enable signal is set to be short;

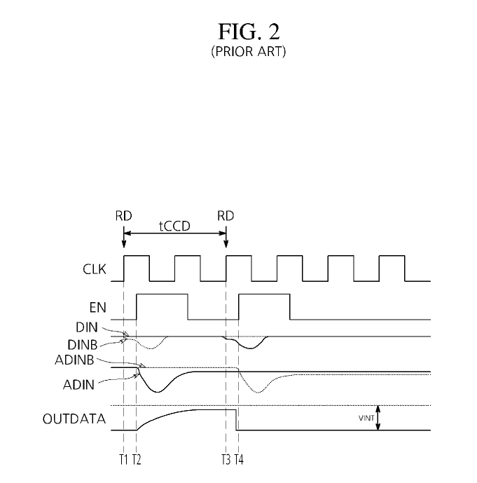

FIG. 3 is a timing diagram illustrating a case where the enable period of the enable signal is set to be long;

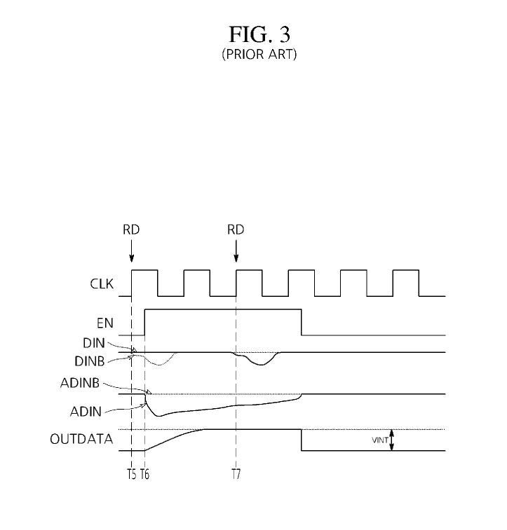

FIG. 4 is a block diagram showing a data output circuit in accordance with an embodiment of the present invention;

FIG. 5 is a circuit diagram of the signal generation unit included in the data output circuit shown in FIG. 4;

FIG. 6 is a circuit diagram of the output unit included in the data output circuit shown in FIG. 4;

FIG. 7 is a timing diagram illustrating operations of the data output circuit shown in FIG. 4;

FIG. 8 is a block diagram showing a semiconductor memory device in accordance with another embodiment of the present invention;

FIG. 9 is a circuit diagram of the signal generation unit included in the semiconductor memory device shown in FIG. 8;

FIG. 10 is a circuit diagram of the precharge signal generation unit included in the semiconductor memory device shown in FIG. 8; and

FIG. 11 is a timing diagram illustrating operations of the semiconductor memory device shown in FIG. 8.

### DETAILED DESCRIPTION

Hereinafter, embodiments of the present invention will be described with reference to the accompanying drawings. The present invention may, however, be embodied in different forms and should not be construed as limited to the embodiments set forth herein.

The drawings are not necessarily to scale and in some instances, proportions may have been exaggerated in order to clearly illustrate features of the embodiments. In this specification, specific terms have been used. The terms are used to describe the present invention, and are not used to qualify the sense or limit the scope of the present invention.

In this specification, ‘and/or’ represents that one or more of components arranged before and after ‘and/or’ is included. Furthermore, ‘connected/coupled’ represents that one component is directly coupled to another component or indirectly coupled through another component. In this specification, a singular form may include a plural form as long as it is not specifically mentioned in a sentence. Furthermore, ‘include/comprise’ or ‘including/comprising’ used in the specification represents that one or more components, steps, operations, and elements exists or are added.

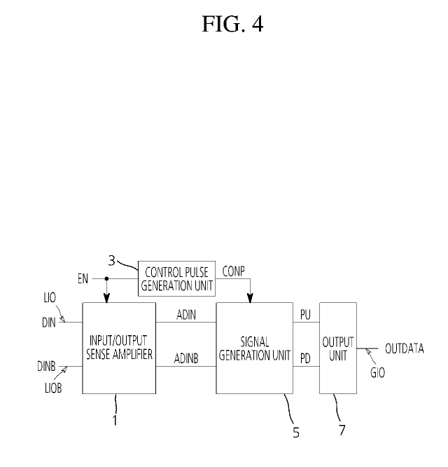

FIG. 4 is a block diagram showing a data output circuit in accordance with an embodiment of the present invention.

Referring to FIG. 4, the data output circuit in accordance with the present embodiment includes an input/output sense amplifier 1, a control pulse generation unit 3, a signal generation unit 5, and an output unit 7.

The input/output sense amplifier 1 is realized in a cross-coupled latch type. The input/output sense amplifier 1 is configured to sense and inversion-amplify data DIN and inverted data DINB respectively transferred through a local line LIO and a complementary local line LIOB, during a period in which an enable signal EN is enabled, and generate amplified data ADIN and inverted amplified data ADINB. The enable signal EN is a signal which is enabled to a logic high level (or a logic low level according to an embodiment) to perform the sensing and amplifying operations of the input/output sense amplifier 1 after a READ command is applied to a semiconductor memory device.

The control pulse generation unit 3 may be realized by a pulse generation unit which is generally known in the art. The control pulse generation unit 3 realized in this way is configured to generate a control pulse CONP in synchronization with a time when the enable signal EN is enabled.

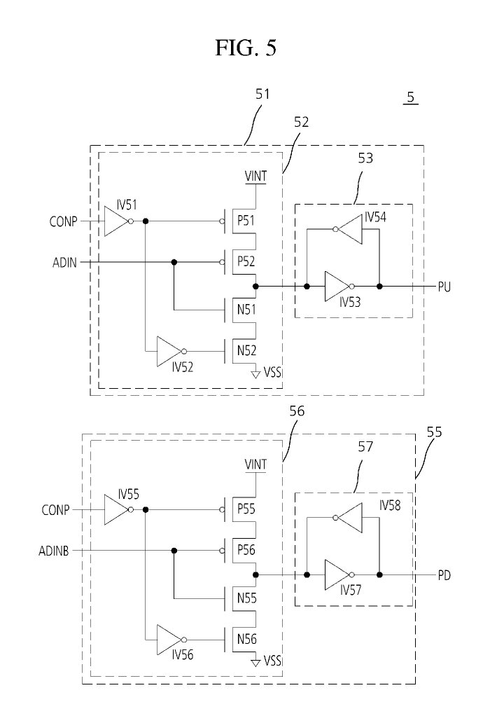

Referring to FIG. 5, the signal generation unit 5 includes a pull-up signal generating section 51 and a pull-down signal generating section 55.

The pull-up signal generating section 51 includes a first buffer part 52 and a first latch part 53. The first buffer part 52 includes two PMOS transistors P51 and P52, two NMOS transistors N51 and N52, and two inverters IV51 and IV52. The first buffer part 52 is configured to buffer the amplified data ADIN when the control pulse CONP is generated. The first latch part 53 includes two inverters IV53 and IV54. The first latch part 53 is configured to latch the output signal of the first buffer part 52 and generate a pull-up signal PU.

The pull-down signal generating section 55 includes a second buffer part 56 and a second latch part 57. The second buffer part 56 includes two PMOS transistors P55 and P56, two NMOS transistors N55 and N56, and two inverters IV55 and IV56. The second buffer part 56 is configured to buffer the inverted amplified data ADINB when the control pulse CONP is generated. The second latch part 57 includes two inverters IV57 and IV58. The second latch part 57 is configured to latch the output signal of the second buffer part 56 and generate a pull-down signal PD.

The signal generation unit 5 configured as mentioned above buffers and latches the amplified data ADIN and the inverted amplified data ADINB when the control pulse CONP is generated, and generates the pull-up signal PU and the pull-down signal PD.

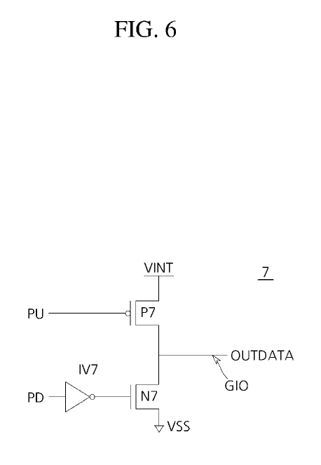

Referring to FIG. 6, the output unit 7 includes one PMOS transistor P7, one NMOS transistors N7, and one inverters IV7. The output unit 7 configured in this way outputs output data OUTDATA of a logic high level to a global line GIO when the pull-up signal PU has a logic low level. Also, the output unit 7 outputs output data OUTDATA of a logic low level to the global line GIO when the pull-down signal PD has a logic low level.

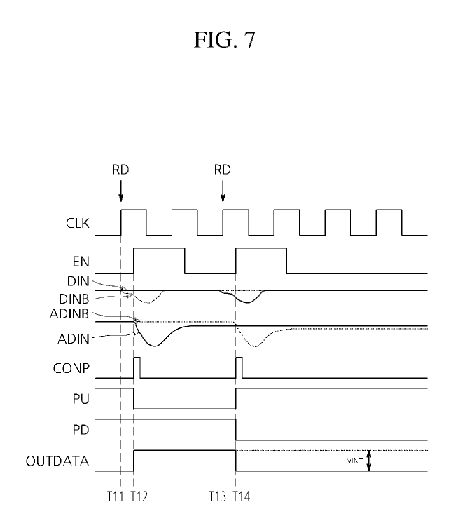

Operations of the data output circuit configured as mentioned above will be described below with reference to FIG. 7. In this example, a first READ command is applied to the semiconductor memory device, and the semiconductor memory device outputs the output data OUTDATA of the logic high level to the global line GIO. A second READ command is applied to the semiconductor memory device after two cycles of a clock CLK, and the semiconductor memory device outputs the output data OUTDATA of the logic low level to the global line GIO.

A first READ command RD is applied to the semiconductor memory device at a time T11, and the enable signal EN is enabled to the logic high level at a time T12.

The input/output sense amplifier 1 senses and inversion-amplifies the data DIN and the inverted data DINB, respectively, transferred through the local line LIO and the complementary local line LIOB, during the period in which the enable signal EN is enabled, and generates the amplified data ADIN and the inverted amplified data ADINB.

The control pulse generation unit 3 generates the control pulse CONP in synchronization with the time when the enable signal EN is enabled.

The signal generation unit 5 buffers and latches the amplified data ADIN of a logic low level when the control pulse CONP is generated, and generates the pull-up signal PU of the logic low level. Also, the signal generation unit 5 buffers and latches the inverted amplified data ADINB of a logic high level when the control pulse CONP is generated, and generates the pull-down signal PD of a logic high level.

The output unit 7 receives the pull-up signal PU of the logic low level and the pull-down signal PD of the logic high level, and outputs the output data OUTDATA of the logic high level to the global line GIO.

When the second READ command RD is applied to the semiconductor memory device at a time T13, the enable signal EN is enabled to the logic high level at a time T14.

The input/output sense amplifier 1 senses and inversion-amplifies the data DIN and the inverted data DINB, respectively, transferred through the local line LIO and the complementary local line LIOB, during the period in which the enable signal EN is enabled, and generates the amplified data ADIN and the inverted amplified data ADINB.

The control pulse generation unit 3 generates the control pulse CONP in synchronization with the time when the enable signal EN is enabled.

The signal generation unit 5 buffers and latches the amplified data ADIN of a logic high level when the control pulse CONP is generated, and generates the pull-up signal PU of a logic high level. Also, the signal generation unit 5 buffers and latches the inverted amplified data ADINB of a logic low level when the control pulse CONP is generated, and generates the pull-down signal PD of the logic low level.

The output unit 7 receives the pull-up signal PU of the logic high level and the pull-down signal PD of the logic low level, and outputs the output data OUTDATA of the logic low level to the global line GIO.

As noted, the control pulse is generated in synchronization with the time when the enable signal EN is enabled. As illustrated in FIG. 7, the pulse width of the control pulse CONP is generally much narrower that the pulse width of the enable signal EN, and the control pulse CONP rises proximate the leading edge of the enable signal EN. The control pulse CONP is applied to the signal generation unit, where the amplified data is buffered and latched, and both the pull-up signal PU and the pull-down signal PD are generated.

The pull-up signal PU and the pull-down signal PD are both applied to the output unit. When the pull-up signal PU has a logic low level, the output unit outputs OUTDATA of a logic high level to the global line GIO. When the pull-down signal PD has a logic low level, the output unit outputs OUTDATA of a logic low level to the global line GIO.

Since PU and PD achieve their proper state in response to the control pulse CONP, and CONP is configured to be generated in synchronization with the time when the enable signal EN is enabled, OUTDATA is properly presented to the global line very near the leading edge of the enable signal EN. Therefore, OUTDATA is properly presented to the global line independent of the enable period of the enable signal EN.

As is apparent from the above descriptions, in the data output circuit in accordance with an embodiment of the present invention, the global line GIO is driven using the pull-up signal PU and the pull-down signal PD which are generated by latching the output signal of the input/output sense amplifier 1. As a consequence, the global line GIO can be driven and the output data OUTDATA can be outputted, regardless of the enable period of the enable signal EN.

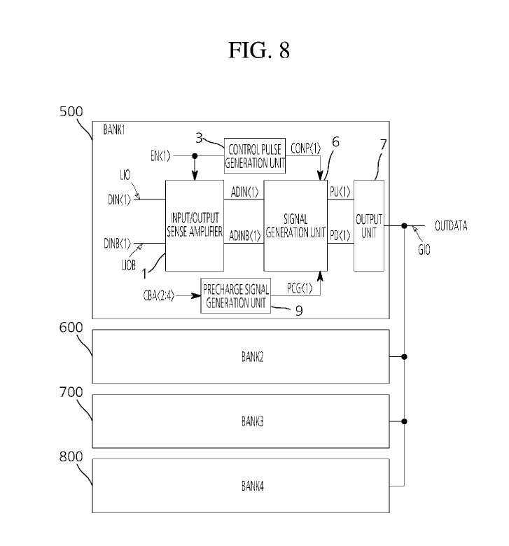

FIG. 8 is a block diagram showing a semiconductor memory device in accordance with another embodiment of the present invention.

Referring to FIG. 8, the semiconductor memory device in accordance with the present embodiment includes first to fourth banks 500 to 800. Signals with <1> mean that they are signals which are inputted to and outputted from the first bank 500.

The first bank 500 includes an input/output sense amplifier 1, a control pulse generation unit 3, a signal generation unit 6, an output unit 7, and a precharge signal generation unit 9. Since the configurations and functions of the input/output sense amplifier 1, the control pulse generation unit 3 and the output unit 7 are the same as those of the data output circuit shown in FIG. 4, descriptions of these elements are omitted here for the sake of brevity.

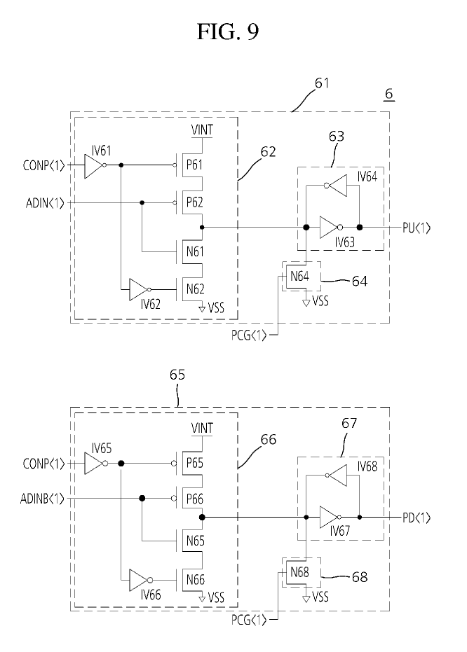

Referring to FIG. 9, the signal generation unit 6 includes a pull-up signal generating section 61 and a pull-down signal generating section 65.

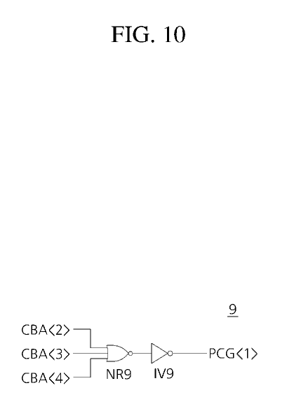

The pull-up signal generating section 61 includes a first buffer part 62, a first latch part 63 and a first precharge part 64. The first buffer part 62 includes two PMOS transistors P61 and P62, two NMOS transistors N61 and N62, and two inverters IV61 and IV62. The first buffer part 62 is configured to buffer amplified data ADIN<1> when a control pulse CONP<1> is generated. The first latch part 63 includes two inverters IV63 and IV64. The first latch part 63 is configured to latch the output signal of the first buffer part 62 and generate a pull-up signal PU<1>. The first precharge part 64 includes an NMOS transistor N64. The first precharge part 64 transitions the pull-up signal PU<1> to a logic high level when a precharge signal PCG<1> has a logic high level. The precharge signal PCG<1> will be described later with reference to FIG. 10.

The pull-up signal generating section 65 includes a second buffer part 66, a second latch part 67 and a second precharge part 68. The second buffer part 66 includes two PMOS transistors P65 and P66, two NMOS transistors N65 and N66, and two inverters IV65 and IV66. The second buffer part 66 is configured to buffer inverted amplified data ADINB<1> when the control pulse CONP<1> is generated. The second latch part 67 includes two inverters IV67 and IV68. The second latch part 67 is configured to latch the output signal of the second buffer part 66 and generate a pull-down signal PD<1>. The second precharge part 68 includes an NMOS transistor N68. The second precharge part 68 transitions the pull-down signal PD<1> to a logic high level when the precharge signal PCG<1> has the logic high level. The precharge signal PCG<1> will be described later with reference to FIG. 10.

The signal generation unit 6 configured as mentioned above inversion-buffers and latches the amplified data ADIN<1> and the inverted amplified data ADINB<1> when the control pulse CONP<1> is enabled to a logic high level, and generates the pull-up signal PU<1> and the pull-down signal PD<1>. Also, the signal generation unit 6 transitions the pull-up signal PU<1> and the pull-down signal PD<1> to the logic high levels when the precharge signal PCG<1> has the logic high level.

Referring to FIG. 10, the precharge signal generation unit 9 includes a NOR gate NR9 and an inverter IV9. The precharge signal generation unit 9 generates the precharge signal PCG<1> of the logic high level when any one of second to fourth column bank signals CBA<2:4> is enabled to a logic high level. The second to fourth column bank signals CBA<2:4> are signals which are enabled to logic high levels when READ or WRITE commands that include a reference to information from the second to fourth banks 600-800 are applied to the semiconductor memory device.

The second bank 600 includes circuitry of the same configuration as described above with respect to the first bank 500, and the precharge signal generation unit (not shown) of the second bank 600 generates the precharge signal PCG of the logic high level when any one of a first column bank signal CBA<1> and the third and fourth column bank signals CBA<3:4> is enabled to the logic high level.

The third bank 700 also includes circuitry of the same configuration as the first bank 500, and the precharge signal generation unit (not shown) of the third bank 700 generates the precharge signal PCG of the logic high level when any one of the first and second column bank signals CBA<1:2> and the fourth column bank signal CBA<4> is enabled to the logic high level.

The fourth bank 800 also includes circuitry of the same configuration as the first bank 500, and the precharge signal generation unit (not shown) of the fourth bank 800 generates the precharge signal PCG of the logic high level when any one of the first to third column bank signals CBA<1:3> is enabled to the logic high level.

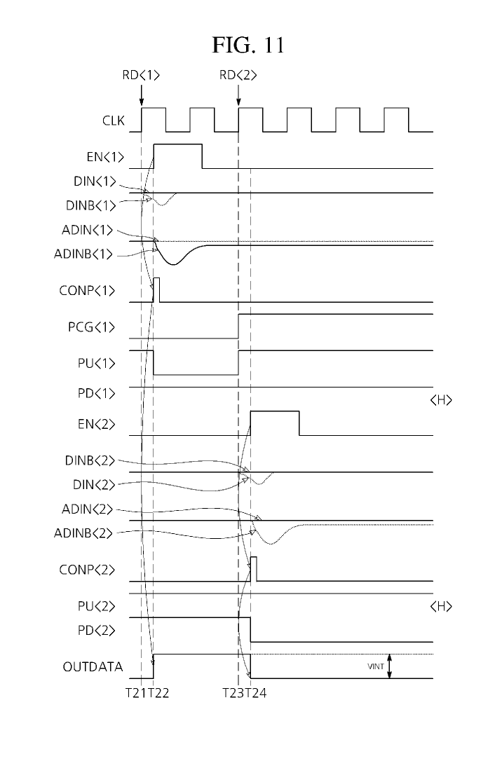

Operations of the semiconductor memory device configured as mentioned above will be described below with reference to FIG. 11. In this example, a READ command RD<1>, including reference to information from the first bank 500, is applied to the semiconductor memory device, and the semiconductor memory device outputs the output data OUTDATA of the logic high level to a global line GIO. When a READ command RD<2>, including reference to information from the second bank 600, is applied to the semiconductor memory device, the semiconductor memory device outputs the output data OUTDATA of the logic low level to the global line GIO. Signals with <1> mean that they are signals which are inputted to or outputted from the first bank 500, and signals with <2> mean that they are signals which are inputted to or outputted from the second bank 600.

When a READ command RD<1>, including reference to information from the first bank 500, is applied to the semiconductor memory device at a time T21, a first enable signal EN<1> is enabled to the logic high level at a time T22.

The input/output sense amplifier 1 senses and inversion-amplifies first data DIN<1> and first inverted data DINB<1>, respectively, transferred through a local line LIO and a complementary local line LIOB, during the period in which the first enable signal EN<1> is enabled, and generates first amplified data ADIN<1> and first inverted amplified data ADINB<1>.

The control pulse generation unit 3 generates a first control pulse CONP<1> in synchronization with the time when the first enable signal EN<1> is enabled.

The signal generation unit 6 inversion-buffers and latches the first amplified data ADIN<1> of a logic low level when the first control pulse CONP is generated, and generates a first pull-up signal PU<1> of a logic low level. Also, the signal generation unit 6 inversion-buffers and latches the first inverted amplified data ADINB<1> of a logic high level when the first control pulse CONP<1> is generated, and generates a first pull-down signal PD<1> of the logic high level.

The output unit 7 receives the first pull-up signal PU<1> of the logic low level and the first pull-down signal PD<1> of the logic high level, and outputs the output data OUTDATA of the logic high level to the global line GIO.

When READ command RD<2>, including reference to information from the second bank 600, is applied to the semiconductor memory device at time T23, since the second column bank signal CBA<2> is enabled to the logic high level, the precharge signal generation unit 9 generates a first precharge signal PCG<1> of the logic high level.

The signal generation unit 6 receives the first precharge signal PCG<1> of the logic high level and transitions the first pull-up signal PU<1> and the first pull-down signal PD<1> to the logic high levels.

Since the output unit 7 receives the first pull-up signal PU<1> of the logic high level and the first pull-down signal PD<1> of the logic high level, it cannot output the output data OUTDATA to the global line GIO.

When the READ command RD<2>, including reference to information from the second bank 600, is applied to the semiconductor memory device at time T23, a second enable signal EN<2> is enabled to the logic high level at time T24.

Second amplified data ADIN<2> and second inverted amplified data ADINB<2> are generated by sensing and inversion-amplifying second data DIN<2> and second inverted data DINB<2>, respectively, transferred through the local line LIO and the complementary local line LIOB.

A second control pulse CONP<2> is generated in synchronization with the time when the second enable signal EN<2> is enabled.

When the second control pulse CONP<2> is generated, the second amplified data ADIN<2> of a logic high level is inversion-buffered and latched, and a second pull-up signal PU<2> of the logic high level is generated. Also, when the second control pulse CONP<2> is generated, the second inverted amplified data ADINB<2> of a logic low level is inversion-buffered and latched, and a second pull-down signal PD<2> of a logic low level is generated.

The output unit (not shown) of the second bank 600 receives the second pull-up signal PU<2> of the logic high level and the second pull-down signal PD<2> of the logic low level, and outputs the output data OUTDATA of the logic low level to the global line GIO.

Having both the pull-up signal PU and the pull-down signal PD at a logic high level would effectively disable the output transistors in the output unit (both the N-channel and P-channel devices would be OFF. That condition occurs when the pre-charge signal for that bank (PCG<1>, for example) is at a logic high level. Since the pre-charge signals are generated through NOR gates having all of the other column bank signals (except the one of interest) as inputs, when bank one is addressed, all of the other output units that share the Global Line are disabled so there is no contention. This is because CBA<1> is an input to the NOR gates that generate PCG signals for all of the other banks except bank 1.

As is apparent from the above descriptions, in the semiconductor memory device in accordance with an embodiment of the present invention, since data is outputted through the global line commonly connected to the first to fourth banks, precharge signal generation units are disposed in the respective banks to prevent contention on the global line.

Embodiments of the present invention have been disclosed above for illustrative purposes. Those skilled in the art will appreciate that various modifications, additions and substitutions are possible, without departing from the scope and spirit of the invention as disclosed in the accompanying claims.

What is claimed is:

1. A data output circuit comprising:
an input/output sense amplifier configured to sense and amplify data and inverted data in response to an enable signal, and generate amplified data and inverted amplified data;
a control pulse generation unit configured to generate a control pulse in synchronization with an enable time of the enable signal; and
a signal generation unit configured to latch the amplified data and the inverted amplified data in response to the control pulse, and generate a pull-up signal and a pull-down signal.

2. The data output circuit according to claim 1, wherein the enable signal is a signal which is generated in response to a read command.

3. The data output circuit according to claim 1, wherein the signal generation unit comprises:
a pull-up signal generating section configured to buffer and latch the amplified data in response to the control pulse, and generate the pull-up signal; and
a pull-down signal generating section configured to buffer and latch the inverted amplified data in response to the control pulse, and generate the pull-down signal.

4. The data output circuit according to claim 3, wherein the pull-up signal generating section comprises:
a first buffer part configured to buffer the amplified data in response to the control pulse; and
a first latch part configured to latch an output signal of the first buffer part and generate the pull-up signal.

5. The data output circuit according to claim 3, wherein the pull-down signal generating section comprises:
a second buffer part configured to buffer the inverted amplified data in response to the control pulse; and
a second latch part configured to latch an output signal of the second buffer part and generate the pull-down signal.

6. The data output circuit according to claim 1, further comprising:
an output unit configured to output an internal voltage or a ground voltage as output data in response to the pull-up signal and the pull-down signal.

7. The data output circuit according to claim 6, wherein the data and the inverted data are respectively loaded on a local line and a complementary local line.

8. The data output circuit according to claim 7, wherein the output data is outputted to a global line.

9. A semiconductor memory device including first to fourth banks, the first bank comprising:
an input/output sense amplifier configured to sense and amplify data and inverted data in response to an enable signal, and generate amplified data and inverted amplified data;
a control pulse generation unit configured to generate a control pulse in synchronization with an enable time of the enable signal;
a precharge signal generation unit configured to generate a precharge signal which is enabled when any one of the second to fourth banks performs a read or write operation; and
a signal generation unit configured to latch the amplified data and the inverted amplified data in response to the control pulse and the precharge signal, and generate a pull-up signal and a pull-down signal.

10. The semiconductor memory device according to claim 9, wherein the enable signal is a signal which is generated in response to a read command.

11. The semiconductor memory device according to claim 9, wherein the precharge signal generation unit generates the precharge signal in response to second to fourth column bank signals which are enabled when the second to fourth banks perform read or write operations.

12. The semiconductor memory device according to claim 9, wherein the signal generation unit comprises:
a pull-up signal generating section configured to buffer and latch the amplified data in response to the control pulse, and generate the pull-up signal; and
a pull-down signal generating section configured to buffer and latch the inverted amplified data in response to the control pulse, and generate the pull-down signal.

13. The semiconductor memory device according to claim 12, wherein the pull-up signal generating section comprises:
a first buffer part configured to buffer the amplified data in response to the control pulse and the precharge signal; and
a first latch part configured to latch an output signal of the first buffer part and generate the pull-up signal.

14. The semiconductor memory device according to claim 12, wherein the pull-down signal generating section comprises:
a second buffer part configured to buffer the inverted amplified data in response to the control pulse and the precharge signal; and
a second latch part configured to latch an output signal of the second buffer part and generate the pull-down signal.

15. The semiconductor memory device according to claim 9, further comprising:
an output unit configured to output an internal voltage or a ground voltage as output data in response to the pull-up signal and the pull-down signal.

16. The semiconductor memory device according to claim 15, wherein the data and the inverted data are respectively loaded on a local line and a complementary local line.

17. The semiconductor memory device according to claim 16, wherein the output data is outputted to a global line.

18. A method of ensuring that a READ operation is properly performed even when a subsequent READ command is received after two or a predetermined number of clock cycles, the method comprising the steps of:
generating an internal enable signal in response to receipt of a READ command, the internal enable signal having a leading edge defining a start of an enable period;
generating an internal control pulse proximate the leading edge of the internal enable signal;
applying the internal control pulse to a signal generation unit in which amplified data from memory cells within the semiconductor memory device are buffered and latched;
deriving a pull-up signal and a pull-down signal from the internal control pulse and the amplified data; and
applying the pull-up signal and the pull-down signal to an output unit that presents output data corresponding to the amplified data from the memory cells to a global line in response to the pull-up signal and the pull-down signal;
such that output data is presented to the global line proximate the leading edge of the enable signal, and effectively independent of the enable period of the enable signal.

19. The method in accordance with claim 18, wherein the semiconductor memory device comprises multiple banks with each bank having output units that share a global line, and the method further comprises the steps of:
generating a column bank address signal for a bank whenever a READ or WRITE command references information from said referenced bank;
generating pre-charge signals derived from a combination of column bank address signals; and
coupling the pre-charge signals to the signal generation units;
such that the pre-charge signals for banks that are not referenced act to place both the pull-up and pull-down signals into a logic high level, effectively disabling the output units for banks that are not referenced and minimizing contention on the global lines.

20. The method in accordance with claim 19, wherein the step of generating pre-charge signals further comprises the steps of:
for the signal generation unit of a selected bank, coupling column bank address signals from every bank except the selected bank to the inputs of a NOR gate to generate the pre-charge signal; and
coupling the pre-charge signal to the signal generation unit of the selected bank.
